(19) United States
(12) Patent Application Publication
(10) Pub. No.: US 2026/0020376 A1
(43) Pub. Date: Jan. 15, 2026

(54) PHOTODETECTOR DEVICE AND METHOD

(71) Applicant: Sensors Unlimited, Inc., Princeton, NJ (US)

(72) Inventor: Krishna Linga, Plainsboro, NJ (US)

(21) Appl. No.: 18/769,114

(22) Filed: Jul. 10, 2024

(51) Int. Cl. H10F 77/40; H10F 71/00; H10F 77/124

(52) U.S. Cl. CPC H10F 77/413; H10F 71/1272; H10F 77/1248

(57) ABSTRACT

A photodetector device includes a cathode contact layer, a light absorption layer, and a multilayer broadband anti-reflection coating. The cathode contact layer is configured to provide a cathode contact for the photodetector device and includes a first material. The light absorption layer is configured to absorb electromagnetic waves. The light absorption layer is formed over the cathode contact layer and includes a second material. The first material is lattice-matched to the second material. The multilayer broadband anti-reflection coating is configured to transmit electromagnetic waves incident on the photodetector device to the light absorption layer through the cathode contact layer.

### TECHNICAL FIELD

This disclosure relates generally to focal plane arrays and other imaging devices. More specifically, this disclosure relates to a photodetector device and method.

### BACKGROUND

Focal plane arrays typically include sensors that have a wavelength response that is limited by absorption in the substrate for wavelengths below 950 nm. A conventional technique to address this issue includes thinning the substrate by etching and/or mechanically polishing that layer to decrease the absorption of wavelengths below 950 nm. However, even after reducing the thickness of the substrate to 200 nm, the responsivity of photocarriers from 400 nm to 950 nm remains limited. To address this issue, separate devices are often used to sense the lower wavelengths and the higher wavelengths, which increases the size, weight, power, and cost of the resulting systems.

### SUMMARY

This disclosure relates to a photodetector device and method.

In a first embodiment, a photodetector device includes a cathode contact layer, a light absorption layer, and a multilayer broadband anti-reflection coating. The cathode contact layer is configured to provide a cathode contact for the photodetector device and includes a first material. The light absorption layer is configured to absorb electromagnetic waves. The light absorption layer is formed over the cathode contact layer and includes a second material. The first material is lattice-matched to the second material. The multilayer broadband anti-reflection coating is configured to transmit electromagnetic waves incident on the photodetector device to the light absorption layer through the cathode contact layer.

Any single one or any combination of the following features may be used with the first embodiment. The first material may include highly doped indium gallium arsenide (InGaAs). The second material may include intrinsic InGaAs. The cathode contact layer may have a thickness between about 50 nm and about 200 nm. The light absorption layer may have a thickness of about 3.5 μm. The multilayer broadband anti-reflection coating may be configured to transmit electromagnetic waves having wavelengths between about 400 nm and about 1700 nm. The photodetector device may include a semiconductor layer formed over the light absorption layer. The photodetector device may include a dielectric layer formed over the semiconductor layer. The photodetector device may include a plurality of sensors formed through openings in the dielectric layer. Each of the plurality of sensors may be formed partially within the semiconductor layer and partially within the light absorption layer. The photodetector device may include an overlay metal layer formed over the dielectric layer and the sensors. The photodetector device may include a plurality of anode bumps. Each of the anode bumps may be deposited on a corresponding one of the sensors. The semiconductor layer may include indium phosphide. The dielectric layer may include silicon nitride. Each of the plurality of sensors may be formed by zinc diffusion into the semiconductor layer and the light absorption layer. Each of the plurality of anode bumps may include indium.

In a second embodiment, a photodetector device includes a cathode contact layer, a light absorption layer, a multilayer broadband anti-reflection coating, and a plurality of sensors. The cathode contact layer is configured to provide a cathode contact for the photodetector device and includes a first material. The light absorption layer is configured to absorb electromagnetic waves. The light absorption layer is formed over the cathode contact layer and includes a second material. The first material is lattice-matched to the second material. The multilayer broadband anti-reflection coating is configured to transmit electromagnetic waves incident on the photodetector device to the light absorption layer through the cathode contact layer. The sensors are formed at least partially in the light absorption layer and are configured to sense the electromagnetic waves absorbed by the light absorption layer.

Any single one or any combination of the following features may be used with the second embodiment. The first material may include highly doped InGaAs. The second material may include intrinsic InGaAs. The cathode contact layer may have a thickness between about 50 nm and about 200 nm. The light absorption layer may have a thickness of about 3.5 μm. The multilayer broadband anti-reflection coating may be configured to transmit electromagnetic waves having wavelengths between about 400 nm and about 1700 nm. The photodetector device may include a semiconductor layer formed over the light absorption layer. The photodetector device may include a dielectric layer formed over the semiconductor layer. Each of the plurality of sensors may be formed through a corresponding opening in the dielectric layer. The photodetector device may include an overlay metal layer formed over the dielectric layer and the sensors. The photodetector device may include a plurality of anode bumps. Each of the anode bumps may be deposited on a corresponding one of the sensors. The photodetector device may include a plurality of cathode metal blocks formed on the cathode contact layer. The photodetector device may include a plurality of cathode bumps. Each of the cathode bumps may be deposited on a corresponding one of the cathode metal blocks. The semiconductor layer may include indium phosphide. The dielectric layer may include silicon nitride. Each of the plurality of sensors may be formed by zinc diffusion into the semiconductor layer and the light absorption layer. Each of the plurality of anode bumps may include indium. Each of the plurality of cathode bumps may include indium.

In a third embodiment, a method includes forming a substrate for a photodetector device. The method also includes forming a cathode contact layer that includes a first material over the substrate. The method further includes forming a light absorption layer that includes a second material over the cathode contact layer. The first material is lattice-matched to the second material. The method also includes removing the substrate from the photodetector device to expose a side of the cathode contact layer opposite the light absorption layer. In addition, the method includes depositing a multilayer broadband anti-reflection coating along the exposed side of the cathode contact layer to transmit electromagnetic waves incident on the photodetector device to the light absorption layer through the cathode contact layer. The transmitted electromagnetic waves have wavelengths between about 400 nm and about 1700 nm.

Any single one or any combination of the following features may be used with the third embodiment. Removing the substrate from the photodetector device to expose the side of the cathode contact layer may include using a chemical etch that is selective to the cathode contact layer to remove the substrate. The method may include forming a semiconductor layer over the light absorption layer. The method may include forming a dielectric layer over the semiconductor layer. The method may include forming a plurality of sensors through openings in the dielectric layer. Each of the plurality of sensors may be formed partially within the semiconductor layer and partially within the light absorption layer. The method may include forming an overlay metal layer over the dielectric layer and the sensors. The method may include depositing each of a plurality of anode bumps on a corresponding one of the sensors. The method may include forming a plurality of cathode metal blocks on the cathode contact layer. The method may include depositing each of a plurality of cathode bumps on a corresponding one of the cathode metal blocks.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIG. 1 is a schematic cross-sectional diagram illustrating an example of a portion of the formation of a photodetector device according to this disclosure;

FIG. 2 is a schematic cross-sectional diagram illustrating an example of a photodetector device according to this disclosure;

FIG. 3 illustrates a graph of an example of quantum efficiency for the photodetector device of FIG. 2 according to this disclosure; and

FIG. 4 illustrates an example of a method for forming the photodetector device of FIG. 2 according to this disclosure.

### DETAILED DESCRIPTION

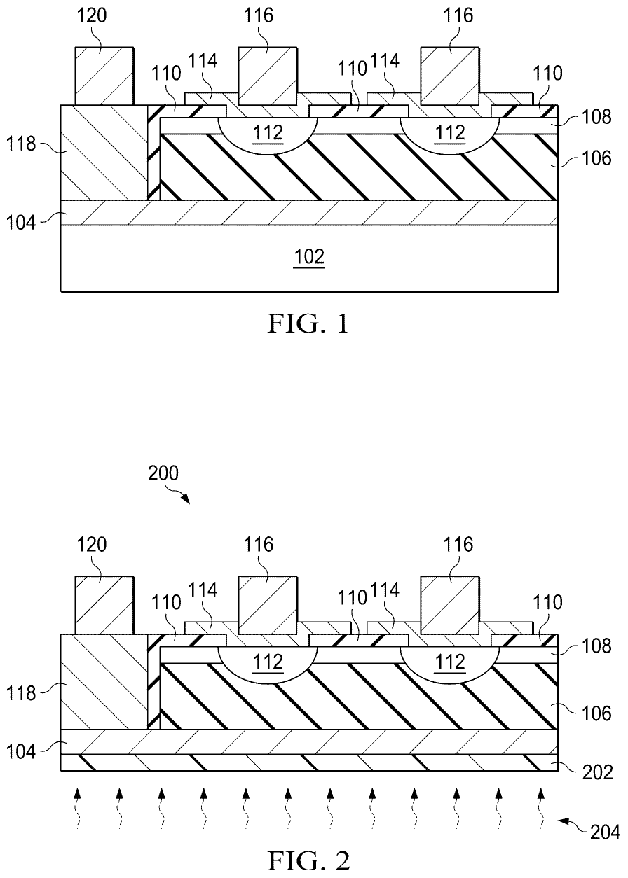

FIGS. 1 through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, focal plane arrays typically include sensors that have a wavelength response that is limited by absorption in the substrate for wavelengths below 950 nm. A conventional technique to address this issue includes thinning the substrate, which also acts as a cathode contact, by etching and/or mechanically polishing that layer to decrease the absorption of wavelengths below 950 nm. However, even after reducing the thickness of the substrate to 200 nm, the responsivity of photocarriers from 400 nm to 950 nm remains limited. To address this issue, separate devices are often used to sense the lower wavelengths and the higher wavelengths, which increases the size, weight, power, and cost of the resulting systems.

This disclosure provides various techniques for achieving a high quantum efficiency broadband wavelength response for a focal plane array that reduces or eliminates the need for separate devices, such as for visible and near infrared wavelengths. In addition, the disclosed techniques can reduce or eliminate tedious mechanical substrate thinning processes. As a result, a focal plane array can be implemented that provides significant improvements in quantum efficiency at lower wavelengths, which increases the signal-to-noise ratio and hence results in improved image quality.

FIG. 1 is a schematic cross-sectional diagram illustrating an example of a portion of the formation of a photodetector device according to this disclosure. The embodiment of the formation of the photodetector device shown in FIG. 1 is for illustration only. Other embodiments of the formation of the photodetector device could be used without departing from the scope of this disclosure.

According to embodiments of this disclosure, the formation of the photodetector device includes the formation of a substrate 102, a cathode contact layer 104, a light absorption layer 106, a semiconductor layer 108, a dielectric layer 110, a plurality of sensors 112, an overlay metal layer 114, a plurality of anode bumps 116, a plurality of cathode metal blocks 118, and a plurality of cathode bumps 120. The substrate 102 may be formed on a wafer (not shown in FIG. 1). The substrate 102 may be epitaxially grown on the wafer or formed by any other suitable technique. The substrate 102 may comprise indium phosphide (InP) or other suitable material. For some embodiments, the substrate 102 may have a thickness of about 50 μm to about 600 μm.

The cathode contact layer 104 is formed over the substrate 102. The cathode contact layer 104 is configured to provide an etch stop for removing the substrate 102 and to provide a cathode contact, as described in more detail below. The cathode contact layer 104 may be epitaxially grown over the substrate 102 or formed by any other suitable technique. For some embodiments, the cathode contact layer 104 may have a thickness between about 50 nm and about 200 nm. For a specific embodiment, the cathode contact layer 104 may have a thickness of about 100 nm.

The light absorption layer 106 is formed over the cathode contact layer 104. The light absorption layer 106 is configured to absorb electromagnetic waves, as described in more detail below. The light absorption layer 106 may be epitaxially grown over the cathode contact layer 104 or formed by any other suitable technique. The light absorption layer 106 may comprise intrinsic indium gallium arsenide (InGaAs) or other suitable material. The cathode contact layer 104 comprises a material that is lattice-matched with the light absorption layer 106. As used herein, the term, “lattice-matched” means that any lattice mismatch between the cathode contact layer 104 and the light absorption layer 106 is less than about 1%. Thus, for embodiments in which the light absorption layer 106 comprises intrinsic InGaAs, the cathode contact layer 104 may comprise highly doped n++ InGaAs or other material that is lattice-matched with intrinsic InGaAs to avoid the introduction of defects. For some embodiments, the light absorption layer 106 may have a thickness of about 3.5 μm.

The semiconductor layer 108 is formed over the light absorption layer 106. The semiconductor layer 108 may be epitaxially grown over the light absorption layer 106 or formed by any other suitable technique. The semiconductor layer 108 may comprise InP or other suitable material. For some embodiments, the semiconductor layer 108 may have a thickness of about 1.0 μm. The dielectric layer 110 is formed over the semiconductor layer 108. The dielectric layer 110 may be epitaxially grown over the semiconductor layer 108 or formed by any other suitable technique. The dielectric layer 110 may comprise silicon nitride (Si₃N₄) or other suitable material.

For each sensor 112, the dielectric layer 110 is etched to expose the semiconductor layer 108. The dielectric layer 110 may be etched using any suitable etching technique that is selective to the material of the semiconductor layer 108 to provide the openings. After the dielectric layer 110 is etched, the sensors 112 may be formed partially in the semiconductor layer 108 and partially in the light absorption layer 106 by diffusion of zinc of other suitable technique to form P+ areas within the photodetector device. The sensors 112 are configured to sense the electromagnetic waves absorbed by the light absorption layer 106, as described in more detail below.

After formation of the sensors 112, the overlay metal layer 114 is deposited over the dielectric layer 110 and the sensors 112. For some embodiments, the overlay metal layer 114 may comprise gold germanium nickel (AuGeNi), gold nickel titanium (AuNiTi), gold nickel (AuNi), titanium nickel (TiNi), titanium platinum gold (TiPtAu), titanium platinum (TiPt), or any other suitable metal or metal alloy. The anode bumps 116 are deposited on the overlay metal layer 114 above the sensors 112 in any suitable manner. The anode bumps 116 may comprise indium or other suitable material.

Each cathode metal block 118 is formed over the cathode contact layer 104 in any suitable manner. For some embodiments, the cathode metal blocks 118 may comprise AuGeNi, AuNiTi, AuNi, TiNi, TiPtAu, TiPt, or any other suitable metal or metal alloy. A cathode bump 120 is deposited on each cathode metal block 118 in any suitable manner. The cathode bumps 120 may comprise indium or other suitable material.

Although FIG. 1 illustrates one example of a schematic cross-sectional diagram illustrating a portion of the formation of the photodetector device, various changes may be made to FIG. 1. For instance, the photodetector device may include additional components not shown in FIG. 1. Also, note that the view shown in FIG. 1 is not to scale.

FIG. 2 is a schematic cross-sectional diagram illustrating an example of the photodetector device 200 according to this disclosure. The embodiment of the photodetector device 200 shown in FIG. 2 is for illustration only. Other embodiments of the photodetector device 200 could be used without departing from the scope of this disclosure.

According to embodiments of this disclosure, the substrate 102 is removed from the photodetector device 200 by chemical etching or other suitable technique. The etching is selective to the material of the cathode contact layer 104. In this way, the cathode contact layer 104 is configured to provide an etch stop to allow the removal of substantially all of the substrate 102.

After removal of the substrate 102, a multilayer broadband anti-reflection coating 202 is deposited along the exposed side of the cathode contact layer 104. The multilayer broadband anti-reflection coating 202 is configured to transmit electromagnetic waves 204 having a broad spectrum of electromagnetic wavelengths into the light absorption layer 106 through the cathode contact layer 104 and to prevent their reflection off the surface of the photodetector device 200. For some embodiments, the multilayer broadband anti-reflection coating 202 is configured to transmit electromagnetic waves 204 having wavelengths between about 400 nm and about 1700 nm. However, it will be understood that the multilayer broadband anti-reflection coating 202 may also be configured to transmit additional wavelengths outside this range.

During use of the photodetector device 200, electromagnetic waves 204 incident on the photodetector device 200 at the multilayer broadband anti-reflection coating 202 can be transmitted through the multilayer broadband anti-reflection coating 202, the cathode contact layer 104, and the light absorption layer 106 to the sensors 112. Each of the sensors 112 is configured to provide a detection signal to a readout integrated circuit (not shown in FIG. 2) or other suitable component coupled to the anode bumps 116 and the cathode bumps 120 of the photodetector device 200 for processing. For example, a readout integrated circuit may be configured to sense current generated by the anode bumps 116 and cathode bumps 120 when electromagnetic waves 204 are detected by the sensors 112 of the photodetector device 200.

Using the photodetector device 200 in a focal plane array results in high quantum efficiency response for electromagnetic waves 204 between about 400 nm and about 1700 nm incident on the anti-reflection coating 202. Thus, while conventional focal plane arrays may require the use of separate visible and short wave infrared sensors, each sensor 112 of the photodetector device 200 provides this broad spectrum response capability. In addition, the photodetector device 200 eliminates the need to precisely polish a substrate by instead completely removing the substrate 102, using the cathode contact layer 104 as both an etch stop layer and a cathode contact. Mechanical polishing, which can introduce defects, is also not required, as the substrate 102 can be removed with a chemical etch process. By depositing the multilayer broadband anti-reflection coating 202 on the exposed cathode contact layer 104, substantially the entire spectrum may be covered instead of only a small wavelength span as with a typical anti-reflection coating.

Although FIG. 2 illustrates one example of a schematic cross-sectional diagram illustrating the photodetector device 200, various changes may be made to FIG. 2. For instance, the photodetector device 200 may include additional components not shown in FIG. 2. In addition, it will be understood that, depending on the application, the photodetector device 200 may include thousands of the sensors 112, anode bumps 116, cathode metal blocks 118, and cathode bumps 120. For particular embodiments, the photodetector device 200 may comprise a PIN photodetector array device. Also, note that the view shown in FIG. 2 is not to scale.

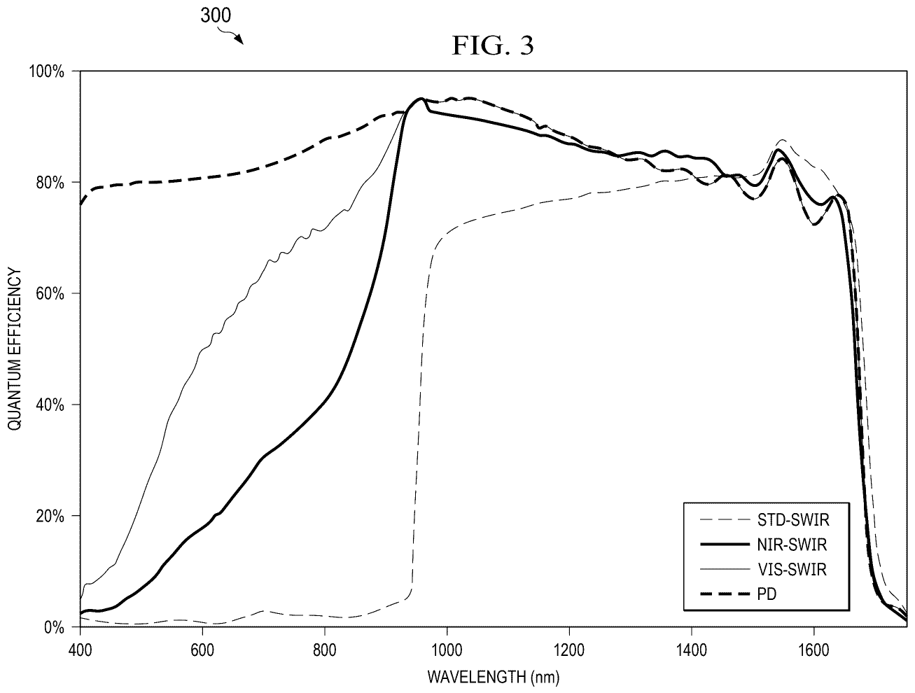

FIG. 3 illustrates a graph 300 of an example of quantum efficiency for the photodetector device 200 according to this disclosure. As shown in the graph 300, the quantum efficiency of a conventional sensor in a focal plane array is minimal for wavelengths below about 950 nm, as seen by the standard, short wave infrared (STD-SWIR) line. Using the conventional technique of thinning a substrate layer by etching and/or mechanically polishing the layer, even down to a thickness of about 200 nm, the quantum efficiency for photocarriers between about 400 nm and 950 nm remains limited, as seen by the near-infrared (NIR-SWIR) and visible light (VIS-SWIR) lines. However, according to embodiments of this disclosure, the quantum efficiency of the photodetector device 200 is greatly improved for the entire range of about 400 nm to about 1700 nm, as seen by the photodetector device (PD) line, compared to both a standard conventional device and a conventional device using a thinned substrate layer.

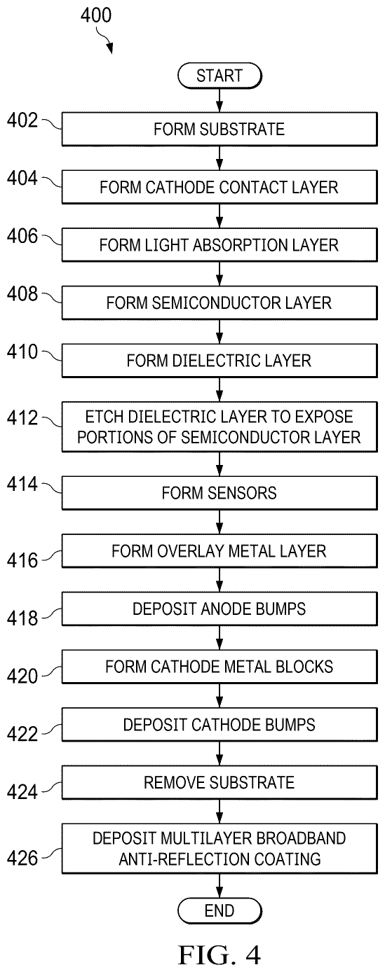

FIG. 4 illustrates an example of a method 400 for forming the photodetector device 200 according to this disclosure. As shown in FIG. 4, the substrate 102 is formed at step 402. This may include, for example, forming the substrate 102 on a wafer. The substrate 102 may be epitaxially grown on the wafer or formed by any other suitable technique. The substrate 102 may comprise indium phosphide (InP) or other suitable material. For some embodiments, the substrate 102 may have a thickness of about 50 μm to about 600 μm.

The cathode contact layer 104 is formed at step 404. This may include, for example, forming the cathode contact layer 104 over the substrate 102. The cathode contact layer 104 may be epitaxially grown over the substrate 102 or formed by any other suitable technique. For some embodiments, the cathode contact layer 104 may have a thickness between about 50 nm and about 200 nm. For a specific embodiment, the cathode contact layer 104 may have a thickness of about 100 nm. The cathode contact layer 104 comprises a material that is lattice-matched with the light absorption layer 106 to avoid the introduction of defects.

The light absorption layer 106 is formed at step 406. This may include, for example, forming the light absorption layer 106 over the cathode contact layer 104. The light absorption layer 106 may be epitaxially grown over the cathode contact layer 104 or formed by any other suitable technique. The light absorption layer 106 may comprise intrinsic InGaAs or other suitable material. For embodiments in which the light absorption layer 106 comprises intrinsic InGaAs, the cathode contact layer 104 may comprise highly doped n++ InGaAs or other material that is lattice-matched with intrinsic InGaAs. For some embodiments, the light absorption layer 106 may have a thickness of about 3.5 μm.

The semiconductor layer 108 is formed at step 408. This may include, for example, forming the semiconductor layer 108 over the light absorption layer 106. The semiconductor layer 108 may be epitaxially grown over the light absorption layer 106 or formed by any other suitable technique. The semiconductor layer 108 may comprise InP or other suitable material. For some embodiments, the semiconductor layer 108 may have a thickness of about 1.0 μm.

The dielectric layer 110 is formed at step 410. This may include, for example, forming the dielectric layer 110 over the semiconductor layer 108. The dielectric layer 110 may be epitaxially grown over the semiconductor layer 108 or formed by any other suitable technique. The dielectric layer 110 may comprise silicon nitride (Si₃N₄) or other suitable material. The dielectric layer 110 is etched to expose portions of the semiconductor layer 108 at step 412. This may include, for example, etching the dielectric layer 110 using any suitable etching technique that is selective to the material of the semiconductor layer 108 to provide openings for the sensors 112. The sensors 112 are formed at step 414. This may include, for example, a diffusion of zinc through the semiconductor layer 108 and into the light absorption layer 106 to form P+ areas within the photodetector device 200. However, the sensors 112 may be formed by any other suitable technique.

The overlay metal layer 114 is formed at step 416. This may include, for example, depositing the overlay metal layer 114 over the dielectric layer 110 and the sensors 112. For some embodiments, the overlay metal layer 114 may comprise AuGeNi, AuNiTi, AuNi, TiNi, TiPtAu, TiPt, or any other suitable metal or metal alloy. The anode bumps 116 are deposited at step 418. This may include, for example, depositing the anode bumps 116 on the overlay metal layer 114 above the sensors 112 in any suitable manner. The anode bumps 116 may comprise indium or other suitable material.

The cathode metal blocks 118 are formed at step 420. This may include, for example, depositing the cathode metal blocks 118 on the cathode contact layer 104. For some embodiments, the cathode metal blocks 118 may comprise AuGeNi, AuNiTi, AuNi, TiNi, TiPtAu, TiPt, or any other suitable metal or metal alloy. The cathode bumps 120 are deposited at step 422. This may include, for example, depositing the cathode bumps 120 on the cathode metal blocks 118 in any suitable manner. The cathode bumps 120 may comprise indium or other suitable material.

The substrate 102 is removed from the photodetector device 200 at step 424. This may include, for example, removing the substrate 102 by chemical etching or other suitable technique to expose a side of the cathode contact layer 104 opposite the light absorption layer 106. The etching is selective to the material of the cathode contact layer 104. In this way, the cathode contact layer 104, in addition to acting as a cathode contact, is configured to provide an etch stop to allow the removal of substantially all of the substrate 102 without the possibility of the introduction of defects that may be caused as a result of using a mechanical etch process on the substrate 102.

The multilayer broadband anti-reflection coating 202 is deposited at step 426. This may include, for example, depositing the multilayer broadband anti-reflection coating 202 along the exposed side of the cathode contact layer 104. The multilayer broadband anti-reflection coating 202 is configured to transmit electromagnetic waves 204 having a broad spectrum of electromagnetic wavelengths and to prevent their reflection off the surface of the photodetector device 200. For some embodiments, the multilayer broadband anti-reflection coating 202 is configured to transmit electromagnetic waves 204 having wavelengths between about 400 nm to about 1700 nm. However, it will be understood that the multilayer broadband anti-reflection coating 202 may also be configured to transmit additional wavelengths outside this range.

In this way, high quantum efficiency may be provided for the response of the photodetector device 200 for electromagnetic waves 204 between about 400 nm and about 1700 nm incident on the multilayer broadband anti-reflection coating 202. Thus, while conventional focal plane arrays may require the use of separate visible and short wave infrared sensors, the disclosed photodetector device 200 provides broad spectrum response capability from each sensor 112. In addition, the photodetector device 200 eliminates the need to precisely polish a substrate by instead completely removing the substrate 102, using the cathode contact layer 104 as both an etch stop layer and a cathode contact. Mechanical polishing, which can introduce defects, is also not required, as the substrate 102 can be removed with a chemical etch process. By depositing the multilayer broadband anti-reflection coating 202 on the exposed cathode contact layer 104, substantially the entire spectrum may be covered instead of only a small wavelength span as with a typical anti-reflection coating.

Although FIG. 4 illustrates one example of a method 400 for forming the photodetector device 200, various changes may be made to FIG. 4. For example, while shown as a series of steps, various steps in FIG. 4 may overlap, occur in parallel, occur in a different order, or occur any number of times (including zero times). In addition, it will be understood that additional steps may be included, such as steps to form openings for the cathode metal blocks 118, attaching a readout integrated circuit, and the like.

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 116(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 116(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A photodetector device comprising:
a cathode contact layer configured to provide a cathode contact for the photodetector device, wherein the cathode contact layer comprises a first material;
a light absorption layer configured to absorb electromagnetic waves, wherein the light absorption layer is formed over the cathode contact layer and comprises a second material, and wherein the first material is lattice-matched to the second material; and
a multilayer broadband anti-reflection coating configured to transmit electromagnetic waves incident on the photodetector device to the light absorption layer through the cathode contact layer.

2. The photodetector device of claim 1, wherein:
the first material comprises highly doped indium gallium arsenide (InGaAs); and
the second material comprises intrinsic InGaAs.

3. The photodetector device of claim 1, wherein:
the cathode contact layer has a thickness between about 50 nm and about 200 nm; and
the light absorption layer has a thickness of about 3.5 μm.

4. The photodetector device of claim 1, wherein the multilayer broadband anti-reflection coating is configured to transmit electromagnetic waves having wavelengths between about 400 nm and about 1700 nm.

5. The photodetector device of claim 1, further comprising:
a semiconductor layer formed over the light absorption layer.

6. The photodetector device of claim 5, further comprising:
a dielectric layer formed over the semiconductor layer; and
a plurality of sensors formed through openings in the dielectric layer, wherein each of the plurality of sensors is formed partially within the semiconductor layer and partially within the light absorption layer.

7. The photodetector device of claim 6, further comprising:
an overlay metal layer formed over the dielectric layer and the sensors; and
a plurality of anode bumps, wherein each of the anode bumps is deposited on a corresponding one of the sensors.

8. The photodetector device of claim 7, wherein:
the semiconductor layer comprises indium phosphide;
the dielectric layer comprises silicon nitride;
each of the plurality of sensors is formed by zinc diffusion into the semiconductor layer and the light absorption layer; and
each of the plurality of anode bumps comprises indium.

9. A photodetector device comprising:
a cathode contact layer configured to provide a cathode contact for the photodetector device, wherein the cathode contact layer comprises a first material;
a light absorption layer configured to absorb electromagnetic waves, wherein the light absorption layer is formed over the cathode contact layer and comprises a second material, and wherein the first material is lattice-matched to the second material;
a multilayer broadband anti-reflection coating configured to transmit electromagnetic waves incident on the photodetector device to the light absorption layer through the cathode contact layer; and
a plurality of sensors configured to sense the electromagnetic waves absorbed by the light absorption layer, wherein the plurality of sensors is formed at least partially in the light absorption layer.

10. The photodetector device of claim 9, wherein:
the first material comprises highly doped indium gallium arsenide (InGaAs); and
the second material comprises intrinsic InGaAs.

11. The photodetector device of claim 9, wherein:
the cathode contact layer has a thickness between about 50 nm and about 200 nm; and
the light absorption layer has a thickness of about 3.5 μm.

12. The photodetector device of claim 9, wherein the multilayer broadband anti-reflection coating is configured to transmit electromagnetic waves having wavelengths between about 400 nm and about 1700 nm.

13. The photodetector device of claim 9, further comprising:
a semiconductor layer formed over the light absorption layer.

14. The photodetector device of claim 13, further comprising:
a dielectric layer formed over the semiconductor layer;
wherein each of the plurality of sensors is formed through a corresponding opening in the dielectric layer.

15. The photodetector device of claim 14, further comprising:
an overlay metal layer formed over the dielectric layer and the sensors;
a plurality of anode bumps, wherein each of the anode bumps is deposited on a corresponding one of the sensors;
a plurality of cathode metal blocks formed on the cathode contact layer; and
a plurality of cathode bumps, wherein each of the cathode bumps is deposited on a corresponding one of the cathode metal blocks.

16. The photodetector device of claim 15, wherein:
the semiconductor layer comprises indium phosphide;
the dielectric layer comprises silicon nitride;
each of the plurality of sensors is formed by zinc diffusion into the semiconductor layer and the light absorption layer;
each of the plurality of anode bumps comprises indium; and
each of the plurality of cathode bumps comprises indium.

17. A method comprising:
forming a substrate for a photodetector device;
forming a cathode contact layer comprising a first material over the substrate;
forming a light absorption layer comprising a second material over the cathode contact layer, wherein the first material is lattice-matched to the second material;
removing the substrate from the photodetector device to expose a side of the cathode contact layer opposite the light absorption layer; and
depositing a multilayer broadband anti-reflection coating along the exposed side of the cathode contact layer to transmit electromagnetic waves incident on the photodetector device to the light absorption layer through the cathode contact layer, wherein the transmitted electromagnetic waves have wavelengths between about 400 nm and about 1700 nm.

18. The method of claim 17, wherein:
the first material comprises highly doped indium gallium arsenide (InGaAs); and
the second material comprises intrinsic InGaAs.

19. The method of claim 17, wherein removing the substrate from the photodetector device to expose the side of the cathode contact layer comprises using a chemical etch that is selective to the cathode contact layer to remove the substrate.

20. The method of claim 17, further comprising:
forming a semiconductor layer over the light absorption layer;
forming a dielectric layer over the semiconductor layer;
forming a plurality of sensors through openings in the dielectric layer, wherein each of the plurality of sensors is formed partially within the semiconductor layer and partially within the light absorption layer;
forming an overlay metal layer over the dielectric layer and the sensors;
depositing each of a plurality of anode bumps on a corresponding one of the sensors;
forming a plurality of cathode metal blocks on the cathode contact layer; and
depositing each of a plurality of cathode bumps on a corresponding one of the cathode metal blocks.
